(19) United States
(12) Patent Application Publication
(10) Pub. No.: US 2019/0372032 A1
(43) Pub. Date: Dec. 5, 2019

(54) NON-FLEXIBLE SUBSTRATE INCLUDING DISPLAY ELEMENT, AND METHOD OF MANUFACTURING FLEXIBLE DISPLAY DEVICE

(71) Applicant: Sharp Kabushiki Kaisha, Sakai City, Osaka (JP)

(72) Inventors: Seiji KANEKO, Sakai City (JP); Yohsuke KANZAKI, Sakai City (JP); Takao SAITOH, Sakai City (JP); Masahiko MIWA, Sakai City (JP); Masaki YAMANAKA, Sakai City (JP)

(21) Appl. No.: 16/467,513

(22) PCT Filed: Aug. 28, 2017
(86) PCT No.: PCT/JP2017/030790

§ 371 Date: Jun. 7, 2019

(51) Int. Cl. H01L 51/00; H01L 51/52; G02F 1/1333

(52) U.S. Cl. CPC H01L 51/0096; G02F 2001/133302; G02F 1/1333; H01L 51/5256

(57) ABSTRACT

In a right PI layer inclined area, a photosensitive PI layer covering an underlying PI layer exposed from an inorganic film of a moisture-proof layer, a gate insulating layer, a second insulating layer, and a third insulating layer is formed.

### TECHNICAL FIELD

The disclosure relates to a non-flexible substrate including a display element, and a method of manufacturing a flexible display device.

### BACKGROUND ART

In recent years, various flat panel displays have been developed, and particularly, Electro Luminescence (EL) display devices such as Organic EL display devices with Organic Light Emitting Diodes (OLED) and inorganic EL display devices with inorganic light emitting diodes and the like have attracted great attention because they can realize high image quality and low power consumption.

A display device having no backlight, such as an EL display device or a display device with a reflection type liquid crystal display element, is required to be formed as a flexible display device such that the display device can be freely bent.

To realize a highly reliable flexible display device, the following method is generally employed. A step of forming an active element (e.g., a TFT element), which is a high-temperature step included in a process of manufacturing a flexible display device as an essential step, is generally performed on a high heat resistant and non-flexible substrate, for example, on a glass substrate, and then the glass substrate is peeled off to secure flexibility.

PTL 1 describes a method of manufacturing a flexible display device including a Laser Lift Off step (also referred to as an LLO step).

### CITATION LIST

### Patent Literature

PTL 1: WO 2015/008642 (published on Jan. 22, 2015)

### SUMMARY

### Technical Problem

In the method of manufacturing a flexible display device including such LLO step, the LLO step needs to be performed on a large glass substrate (also referred to as a mother glass substrate) from the viewpoint of improving productivity.

In the LLO step, a PI layer needs to be formed, the PI layer being made of, for example, a polyimide resin on one face of a large glass substrate (non-flexible substrate), and the large glass substrate is generally coated with a PI layer by using a slit coater in this case. In a case where necessary, after forming the heat absorption layer, a PI layer made of a polyimide resin may be formed on the heat absorption layer.

However, in the case of a PI layer formed on a large glass substrate by using a slit coater, although a difference in degree occurs depending on the viscosity of a polyimide to be applied, a region having a thinner film thickness than other portions in the PI layer may be formed in the coating start end of the slit coater, in the coating termination end of the slit coater, in the right end in the movement direction of the slit coater and in the left end in the movement direction of the slit coater.

In such a region in which a film thickness of the PI layer is thin, i.e., in end regions of four sides of the large glass substrate, a peeling deficiency may occur in a step (also referred to as a delamination step), included in the LLO step, of peeling the large glass substrate from the PI layer by emitting laser light from the large glass substrate side, thereby causing an ablation at an interface between the PI layer and the large glass substrate.

Since the delamination step is a step that is relatively close to the last during a manufacturing step of the flexible display device, in a case where a peeling deficiency occurs in this delamination step, the yield may be reduced, and the manufacturing cost may also be significantly increased.

In view of the above problems, an object of the disclosure is to provide a non-flexible substrate including a display element that can be manufactured with a high yield and a method of manufacturing a flexible display device. The method can provide a minimized peeling deficiency in a step (delamination step), included in an LLO step, of peeling a large glass substrate from a PI layer made of, for example, a polyimide resin.

### Solution to Problem

To solve the above problem, a method of manufacturing a flexible display device according to the disclosure is a method of manufacturing a flexible display device including a step of forming a first resin layer on one face of a non-flexible substrate. The method includes: a first step of forming the first resin layer such that a film thickness in end regions of the first resin layer including four regions of an upper, a lower, a right, and a left region surrounding a central region of the first resin layer is thinner than a film thickness in the central region of the first resin layer; a second step of forming one or more inorganic films on the first resin layer; a third step of exposing the first resin layer by removing at least a portion of the one or more inorganic films in at least one of the four regions in the end regions of the first resin layer; a fourth step of forming a second resin layer on the first resin layer in a region in which the first resin layer is exposed among the four regions in the end regions of the first resin layer; a fifth step of emitting laser light from a side of the non-flexible substrate to peel the non-flexible substrate; and a sixth step of bonding a flexible substrate to a surface from which the non-flexible substrate is peeled.

According to the above method, since the second resin layer is formed on the first resin layer in at least one of the four regions in the end regions of the first resin layer, a flexible display device may be realized, while suppressing the occurrence of a peeling deficiency in a step (delamination step), included in the LLO step, of peeling a large glass substrate from the first resin layer, even in the first resin layer formed with a thin film thickness.

To solve the above problem, a non-flexible substrate of the disclosure is a non-flexible substrate including a display element on one face of the non-flexible substrate, wherein a first resin layer is formed on the one face and below the display element, a film thickness in end regions of the first resin layer including four regions of an upper, a lower, a right, and a left region surrounding a central region of the first resin layer is thinner than a film thickness in the central region of the first resin layer, one or more inorganic films is formed on the first resin layer, and a second resin layer covering the first resin layer exposed from the one or more inorganic films is formed in at least one of the four regions in the end regions of the first resin layer.

According to the above configuration, since the second resin layer covering the first resin layer exposed from the one or more inorganic films is formed in at least one of the four regions in the end regions of the first resin layer, a non-flexible substrate including a display element may be realized with a high yield, while suppressing the occurrence of a peeling deficiency in a step (delamination step), included in the LLO step, of peeling a large glass substrate from the first resin layer even in the first resin layer formed with a thin film thickness.

Advantage Effects of Disclosure

In accordance with an aspect of the disclosure, it is possible to provide a flexible substrate including a display element that can be manufactured with a high yield and a method of manufacturing a flexible display device which can provide a minimized peeling deficiency in a step (delamination step), included in an LLO step, of peeling a large glass substrate from a PI layer made of a polyimide resin.

### BRIEF DESCRIPTION OF DRAWINGS

FIG. 1 is a diagram showing a change in the film thickness of an underlying PI layer depending on the distance from each PI coating end of a glass substrate.

FIG. 2 is a view of each end of the glass substrate used in FIG. 1.

FIGS. 3A and 3B are views of a pattern in which an underlying PI layer is formed thin in each end of the glass substrate used in FIG. 1.

FIG. 4 is a view illustrating a portion of a glass substrate on which an underlying PI layer is formed.

FIGS. 5A to 5C are diagrams for describing a manufacturing process of a flexible organic EL display device with a bending area (BA).

FIG. 6 is a diagram for describing an example of a manufacturing process for a terminal portion of a flexible organic EL display device illustrated in FIGS. 5A to 5C.

FIGS. 7A to 7C are diagrams for describing a Laser Lift Off step (also referred to as an LLO step) included in a manufacturing process of a flexible organic EL display device.

FIG. 8 is a diagram for describing a manufacturing process and a schematic configuration of a flexible organic EL display device according to a second embodiment.

FIGS. 9A and 9B are diagrams for describing a manufacturing process and a schematic configuration of a flexible organic EL display device according to a third embodiment.

FIG. 10 is a diagram for describing a manufacturing process and a schematic configuration of a flexible organic EL display device according to a fourth embodiment.

FIGS. 11A and 11B are diagrams for describing a manufacturing process and a schematic configuration of a flexible organic EL display device according to a fifth embodiment.

### DESCRIPTION OF EMBODIMENTS

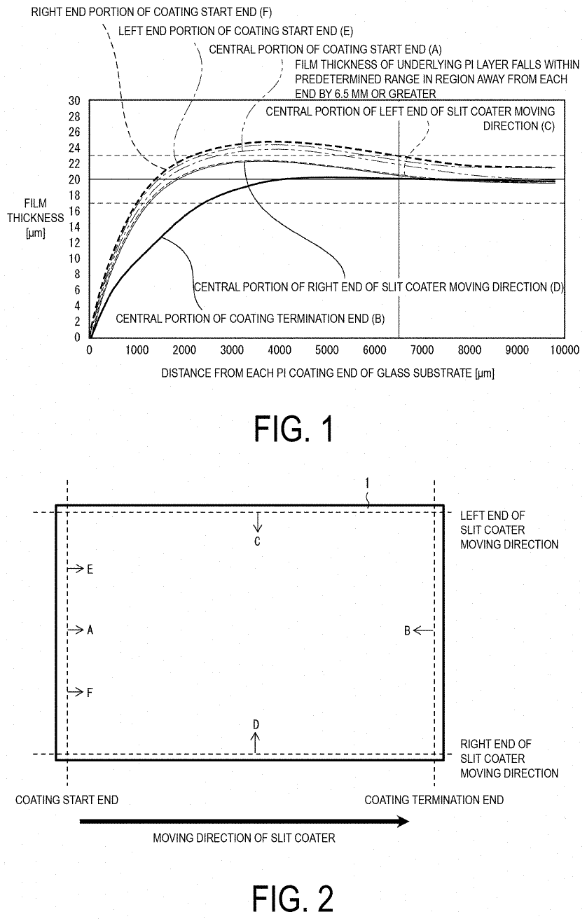

Embodiments of the disclosure will be described below with reference to FIGS. 1 to 11B. Hereinafter, for the convenience of description, a configuration having the same function as that described in a specific embodiment is denoted by the same reference signs, and the description thereof may be omitted.

Further, in the following embodiments, an organic Electro luminescence (EL) element is described as an example of a display element (optical element), but the display element is not limited thereto, and a reflection type liquid crystal display element or the like which is controlled in brightness and transmittance by a voltage and does not require a backlight, for example, may be used.

The display element (optical element) may be an optical element whose brightness and transmittance are controlled by an electric current, and examples of the electric current-controlled optical element include an EL display such as an organic Electro Luminescence (EL) display with an Organic Light Emitting Diode (OLED) and an inorganic EL display with an inorganic light emitting diode, or a QLED display with a Quantum dot Light Emitting Diode (QLED).

### First Embodiment

A first embodiment of the disclosure will be described with reference to FIGS. 1 to 7C.

FIG. 1 is a diagram showing a change in the film thickness of an underlying PI layer 2, which is a first polyimide resin layer (a first resin layer), depending on the distance from each PI coating end of a large glass substrate 1, which is a high heat resistant and non-flexible substrate of the underlying PI layer 2.

FIG. 2 is a view of each end of the glass substrate 1.

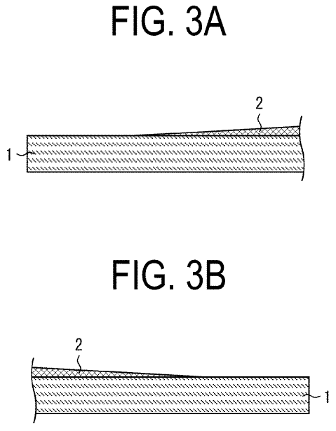

FIGS. 3A and 3B are views illustrating a pattern in which the underlying PI layer 2 is formed thin in each end of the glass substrate 1.

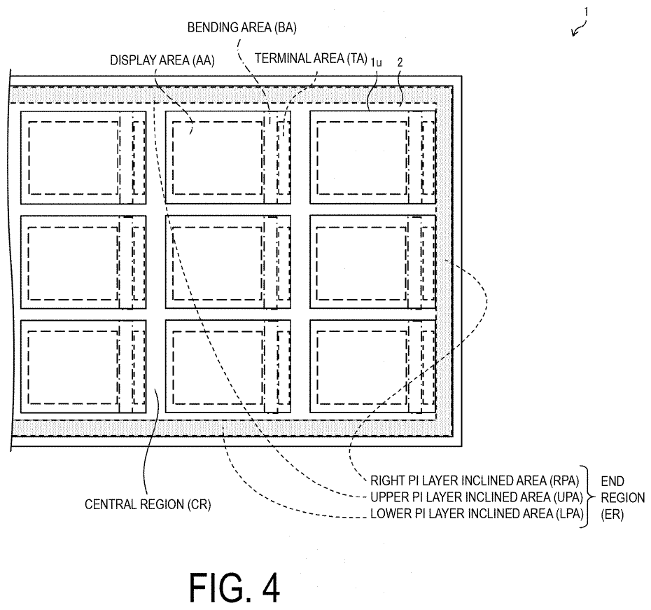

FIG. 4 is a view illustrating a portion of the large glass substrate 1 (mother glass substrate) on which the underlying PI layer 2 is formed. The large glass substrate 1 includes a plurality of organic EL display devices 1u with a display area (AA), a bending area (BA), and a terminal area (TA).

As illustrated in FIG. 2, when the glass substrate 1 is coated with the underlying PI layer 2 while a slit coater is moved from the left to the right in the drawing, the left end in the drawing corresponds to the coating start end, and the right end in the drawing corresponds to the coating termination end, and the upper end in the drawing corresponds to the left end in the slit coater moving direction, and the lower end in the drawing corresponds to the right end in the slit coater moving direction.

As shown in FIG. 1, at the coating start end, the film thickness change of the underlying PI layer 2 in the center portion (A) of the coating start end corresponding to the position of the arrow A in FIG. 2, the film thickness change in the left end portion (E) of the coating start end corresponding to the position of the arrow E in FIG. 2, and the film thickness change in the right end portion (F) of the coating start end corresponding to the position of the arrow F in FIG. 2 are shown. At the coating termination end, the film thickness change of the underlying PI layer 2 in the center portion (B) of the coating termination end corresponding to the position of the arrow B in FIG. 2 is shown. At the left end in the moving direction of the slit coater, the film thickness change of the underlying PI layer 2 in the center portion (C) of the left end in the moving direction of the slit coater corresponding to the position of the arrow C in FIG. 2 is shown. At the right end in the moving direction of the slit coater, the film thickness change of the underlying PI layer 2 in the center portion (D) of the right end in the moving direction of the slit coater corresponding to the position of the arrow D in FIG. 2 is shown.

When the target film thickness of the underlying PI layer 2 formed on the glass substrate 1 is set to, for example, 20 μm, and the allowable maximum film thickness is set to 23 μm, and the allowable minimum film thickness is set to 17 μm, it is understood that the film thickness of the underlying PI layer 2 falls within the allowable film thickness range in a region away from each PI coating end of the glass substrate 1 by 6.5 mm (6500 μm) or more.

On the other hand, as shown in FIG. 1, in a region within 1.0 mm (1000 μm) from each PI coating end of the glass substrate 1, the film thickness of the underlying PI layer 2 is less than the allowable minimum film thickness of 17 μm, and is formed in an inclined shape such that the film thickness becomes thinner from the center portion of the glass substrate 1 toward the end portion thereof.

FIG. 3A is a diagram illustrating the underlying PI layer 2 formed in a region within 1.0 mm from the coating start end of the glass substrate 1, and FIG. 3B is a diagram illustrating the underlying PI layer 2 formed in a region within 1.0 mm from the coating termination end of the glass substrate 1.

In a region within 1.0 mm from each PI coating end of the glass substrate 1, for example, in a portion in which the underlying PI layer 2 having the shape illustrated in FIGS. 3A and 3B is formed, a peeling deficiency may occur in a step (also referred to as a delamination step), included in the LLO step, of peeling the large glass substrate 1 from the underlying PI layer 2 by emitting laser light from the large glass substrate 1 side, thereby causing an ablation at an interface between the underlying PI layer 2 and the large glass substrate 1.

Since this delamination step is a step that is relatively close to the last during a manufacturing process of the flexible organic EL display device, in a case where a peeling deficiency occurs in this delamination step, the yield is reduced, and the manufacturing cost is also significantly increased.

In the present embodiment, a case where a peeling deficiency occurs in the regions within 1.0 mm from each PI coating end of the glass substrate 1 has been described as an example. However, the distance from each PI coating end of the glass substrate 1 in a region where the peeling deficiency occurs depends on the viscosity of the material forming the underlying PI layer 2 or the like.

When the viscosity of the material forming the underlying PI layer 2 is relatively high, the region where the peeling deficiency occurs tends to narrow, and when the viscosity of the material forming the underlying PI layer 2 is relatively low, the region where the peeling deficiency occurs tends to widen.

Additionally, in the present embodiment, the case where the underlying PI layer 2 is directly formed on the glass substrate 1 has been described as an example, but when necessary, after a heat absorption layer (not illustrated) is formed on the glass substrate 1, the underlying PI layer 2 may be formed on the heat absorption layer.

As illustrated in FIG. 4, in the large glass substrate 1 including the plurality of organic EL display devices 1u, for example, a region within 1.0 mm from the end of the underlying PI layer 2 is an end region (ER) of the underlying PI layer 2 formed in an inclined shape in which the film thickness of the underlying PI layer 2 becomes gradually thinner toward the outer side.

As illustrated, the frame shaped end region (ER) of the underlying PI layer 2 includes a right PI layer inclined area (RPA), an upper PI layer inclined area (UPA), a lower PI layer inclined area (LPA), and a left side PI layer inclined area (not illustrated).

The inner side of the frame shaped end region (ER) of the underlying PI layer 2 is the central region (CR) of the underlying PI layer 2, and in the central region (CR) of the underlying PI layer 2, the film thickness of the underlying PI layer 2 is formed substantially uniform within a predetermined range.

Accordingly, a display area (AA), a bending area (BA), a terminal area (TA), and the like included in the organic EL display device 1u are formed by utilizing the central region (CR) of the underlying PI layer 2.

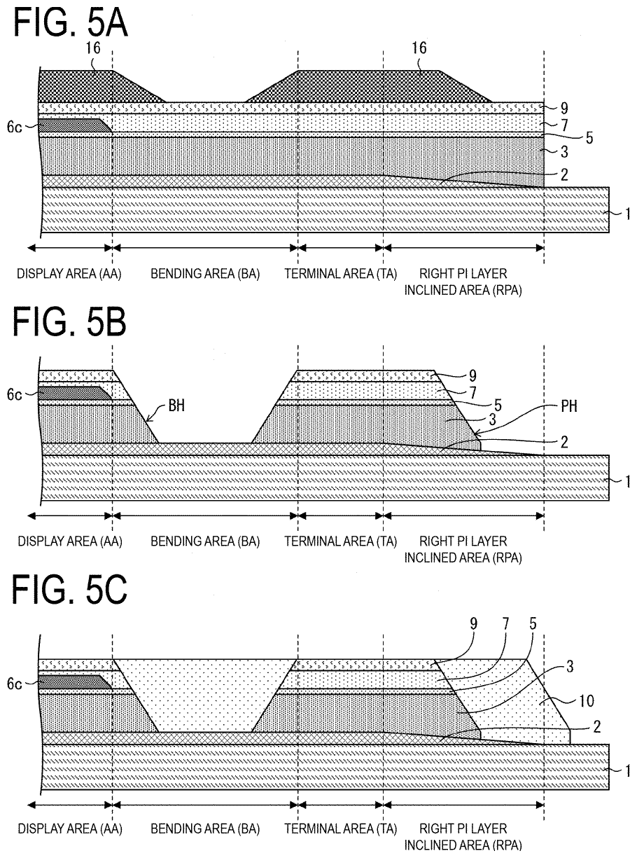

Hereinafter, with reference to FIGS. 5A to 7C, a description will be given below of a reason, even when the glass substrate 1 on which the underlying PI layer 2 having a film thickness less than the allowable minimum film thickness is formed in a region within a predetermined distance from each PI coating end of the glass substrate 1 is used, why a flexible organic EL display device may be manufactured with a high yield, while suppressing the occurrence of a peeling deficiency in a step (delamination step), included in the LLO step, of peeling the glass substrate 1 from the underlying PI layer 2.

In the present embodiment, among the right PI layer inclined area (RPA), the upper PI layer inclined area (UPA), the lower PI layer inclined area (LPA), and the left PI layer inclined area (not illustrated), which are the frame shaped end region (ER) of the underlying PI layer 2, only the right PI layer inclined area (RPA) of the underlying PI layer 2 is configured to be covered with the photosensitive PI layer 10 in the exposed portion. However, the embodiment is not limited thereto, and the exposed portion may be covered with the photosensitive PI layer 10 in one area out of the right PI layer inclined area (RPA), the upper PI layer inclined area (UPA), the lower PI layer inclined area (LPA), the left PI layer inclined area (not illustrated), or in two areas out of them, or in three areas out of them. In addition, it is more preferable that, in all areas (four areas), the exposed portions be covered with the photosensitive PI layer 10.

FIGS. 5A to 5C are diagrams for describing a manufacturing process of a flexible organic EL display device with a bending area (BA).

As illustrated in FIGS. 5A to 5C, a non-display area of a flexible organic EL display device includes a bending area (BA), a terminal area (TA), a right PI layer inclined area (RPA), and in the periphery of the display area (AA), a bending area (BA) adjacent to the display area (AA), the terminal area (TA) outside of the bending area (BA), and the right PI layer inclined area (RPA) outside of the terminal area (TA) are provided.

Note that, as illustrated in FIG. 4, the right PI layer inclined area (RPA) is an area in which the film thickness of the underlying PI layer 2 formed on the glass substrate 1 is thinner than that of the display area (AA), the bending area (BA), and the terminal area (TA).

As illustrated in FIG. 5A, first, the underlying PI layer 2 is applied on the glass substrate 1 as a non-flexible substrate by using a slit coater (not illustrated) (S1 step).

In the underlying PI layer 2, the film thickness of the right PI layer inclined area (RPA) is formed thinner than that of the display area (AA), the bending area (BA) and the terminal area (TA), and in the right PI layer inclined area (RPA), the film thickness becomes thinner from a position closer the terminal area (TA) toward a position away from the terminal area (TA).

In the present embodiment, a case is described in which the glass substrate 1 with high heat resistance is used in consideration of a high temperature step included in a subsequent step and a step in which laser light is passed through the glass substrate 1 in a subsequent step, but the embodiment is not limited thereto as long as the substrate can withstand a high temperature step included in a subsequent step and can transmit laser light in a subsequent step.

Next, as illustrated in FIG. 5A, a moisture-proof layer 3 (also referred to as a barrier layer) is formed on the underlying PI layer 2 (S2 step).

The moisture-proof layer 3 is a layer preventing moisture or impurities from reaching the active element or the display element when the flexible organic EL display device is used, and for example, may be formed, by CVD, of a silicon oxide film, a silicon nitride film, or a silicon oxynitride film, or a layered film of these films.

Then, although not illustrated, in the display area (AA), a semiconductor layer is formed on the moisture-proof layer 3 into a predetermined shape (S3 step). Subsequently, as illustrated in FIG. 5A, a gate insulating layer 5 as a first insulating layer covering the moisture-proof layer 3 and the semiconductor layer is formed in a display area (AA), a bending area (BA), a terminal area (TA), and a right PI layer inclined area (RPA) (S4 step).

The gate insulating layer 5 may be formed, for example, by CVD, of a silicon oxide (SiOx) film or a silicon nitride (SiNx) film or a layered film thereof.

Although not illustrated, in the display area (AA), on the gate insulating layer 5, a gate electrode and a capacitance electrode are formed into a predetermined shape (S5 step), and then a second insulating layer 7 covering the gate insulating layer 5, the gate electrode, the capacitance electrode, and a gate electrode stretching wiring line 6c is formed in the display area (AA), the bending area (BA), the terminal area (TA), and the right PI layer inclined area (S6 step).

The second insulating layer 7 is an insulating film layer for forming a capacitor (capacitance element), and may be a silicon nitride (SiNx) film formed by, for example, CVD.

Next, although not illustrated, in the display area (AA), a capacitance counter electrode overlapping with the capacitance electrode in a plan view are formed into a predetermined shape on the second insulating layer 7 (S7 step), and then a third insulating layer 9 covering the second insulating layer 7 and the capacitance counter electrode is formed in the display area (AA), the bending area (BA), the terminal area (TA), and the right PI layer inclined area (RPA) (S8 step).

The third insulating layer 9 may be formed, for example, by CVD, of a silicon oxide (SiOx) film or a silicon nitride (SiNx) film or a layered film thereof.

Next, as illustrated in FIGS. 5A and 5B, using a resist 16 including an opening in a predetermined portion as a mask, the moisture-proof layer 3, the gate insulating layer 5, the second insulating layer 7, and the third insulating layer 9 are removed to form a bending hole (BH), and the bending area (BA) is formed. Furthermore, using the resist 16 including an opening in a predetermined portion as a mask, the moisture-proof layer 3, the gate insulating layer 5, the second insulating layer 7 and the third insulating layer 9 are removed to form an exposed hole (PH) of the underlying PI layer 2, such that the area of the underlying PI layer 2 having a thin film thickness is exposed in the right PI layer inclined area (RPA) of the underlying PI layer 2 (S9 step).

Note that the bending hole (BH) is preferably formed by removing the entire layered film composed of inorganic film in consideration of the 180 degrees bending and the bending easiness in the bending area (BA) of the flexible organic EL display device, but it may be formed by removing only one or more upper films in the layered film composed of inorganic film.

In the present embodiment, dry etching is performed, and the bending hole (BH) and the exposed hole (PH) of the underlying PI layer 2 are formed, but the embodiment is not limited thereto.

Next, as illustrated in FIG. 5C, the photosensitive PI layer 10 as a second polyimide resin layer (second resin layer) is formed such that the exposed portion of the underlying PI layer 2 is covered with the photosensitive PI layer 10, here, the exposed portion is a portion where the exposed hole (PH) of the underlying PI layer 2 is formed on the underlying PI layer 2 by removing the moisture-proof layer 3, the gate insulating layer 5, the second insulating layer 7, and the third insulating layer 9, and this allows an area having a thin film thickness in the right PI layer inclined area (RPA) of the underlying PI layer 2 to be covered with the photosensitive PI layer 10 (S10 step).

Note that the photosensitive PI layer 10 is preferably formed having a film thickness of not less than a predetermined film thickness such that a total film thickness of the underlying PI layer 2 and the photosensitive PI layer 10 in the right PI layer inclined area (RPA) is not less than a film thickness of the underlying PI layer 2 in the display area (AA), the bending area (BA), and the terminal area (TA).

In the present embodiment, to form the photosensitive PI layer 10 having a film thickness of not less than a predetermined film thickness, the photosensitive PI layer 10 having a thin film thickness is removed by the exposure and development steps, as illustrated in FIG. 5C, like the right end of the photosensitive PI layer 10.

Further, in the present embodiment, the bending hole (BH) of the bending area (BA) is filled with the photosensitive PI layer 10.

The photosensitive PI layer 10 is a polyimide resin including a photosensitive material and may be a positive-working or a negative-working.

Although the photosensitive PI layer 10 is used as the second polyimide resin layer in the present embodiment, the embodiment is not limited thereto. The second polyimide resin layer may be a polyimide resin not including a photosensitive material. In such a case, the right end of the photosensitive PI layer 10 having a shape illustrated in FIG. 5C may be formed by dry etching using a resist film with a predetermined pattern as a mask, the resist film being formed on a polyimide resin not including a photosensitive material.

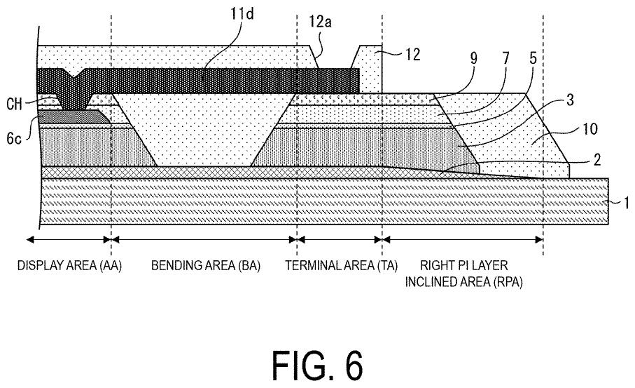

FIG. 6 is a diagram for describing an example of a manufacturing process for a terminal portion of a flexible organic EL display device illustrated in FIGS. 5A to 5C.

As illustrated in FIGS. 5C and 6, after a contact hole (CH) is formed in the second insulating layer 7 and the third insulating layer 9, a lead wiring line 11d in contact with a gate electrode stretching wiring line 6c in the contact hole (CH), is formed into a predetermined shape.

Then, a photosensitive flattening layer 12 as a flattening layer, covering the third insulating layer 9, the photosensitive PI layer 10, and the lead wiring line 11d, is formed in the display area (AA), the bending area (BA), and the terminal area (TA).

In the photosensitive flattening layer 12, an opening 12a overlapping with the lead wiring line 11d in a plan view is provided, and a portion where the lead wiring line 11d is exposed through the opening 12a is a terminal portion.

Note that, although the terminal portion of the configuration illustrated in FIG. 6 is adopted in the present embodiment, the embodiment is not limited thereto. Not to mention, the terminal portion other than the configuration illustrated in FIG. 6 may be adopted.

In the present embodiment, a case where the photosensitive flattening layer 12 is provided in the display area (AA), the bending area (BA), and the terminal area (TA) has been described as an example, but the embodiment is not limited thereto, and the photosensitive flattening layer 12 may be provided in the display area (AA), the bending area (BA), the terminal area (TA), and the right PI layer inclined area (RPA).

Note that, in the present embodiment, a polyimide resin including a photosensitive material is used as the photosensitive flattening layer 12 because the polyimide resin can effectively prevent the penetration of moisture or impurities, but the embodiment is not limited thereto, and the photosensitive flattening layer 12 may also be an acrylic resin including a photosensitive material.

In addition, the photosensitive flattening layer 12 may be either a positive-working or a negative-working, but in the present embodiment, a positive-working resin in which an opening is formed in the exposed part is used.

In the present embodiment, the photosensitive flattening layer 12 is used as a flattening layer, but the flattening layer may be a polyimide resin or an acrylic resin which does not include a photosensitive material, and in such a case, the opening may be formed by dry etching using the resist film formed on a polyimide resin or an acrylic resin not including a photosensitive material and having a predetermined pattern as a mask.

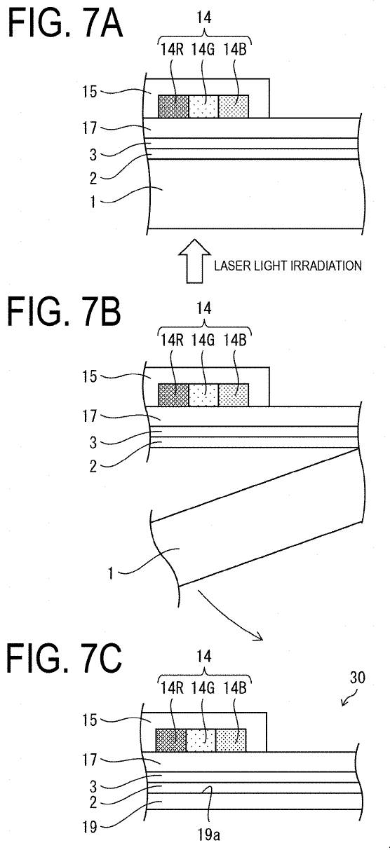

FIGS. 7A to 7C are diagrams for describing a Laser Lift Off step (also referred to as an LLO step) included in the manufacturing process of a flexible organic EL display device.

In addition, in FIGS. 7A to 7C, a layered film of the flexible organic EL display device, which is an upper layer from the moisture-proof layer 3 and a lower layer from a first electrode (not illustrated) included in the display element 14, is illustrated as a layered film 17.

On the layered film 17, a plurality of red light-emitting organic EL elements 14R, a plurality of green light-emitting organic EL elements 14G, and a plurality of blue light-emitting organic EL elements 14B are formed, and a sealing film 15 is formed covering the plurality of red light-emitting organic EL elements 14R, the plurality of green light-emitting organic EL elements 14G, and the plurality of blue light-emitting organic EL elements 14B.

Although not illustrated, an edge cover is formed surrounding each end portion of the first electrode.

Each of the red light-emitting organic EL element 14R, the green light-emitting organic EL element 14G, and the blue light-emitting organic EL element 14B is, for example, although not illustrated, a layered body of a first electrode, a hole injection layer, a hole transport layer, a light-emitting layer of each color, an electron transport layer, an electron injection layer, and a second electrode.

The sealing film 15 covers the red light-emitting organic EL element 14R, the green light-emitting organic EL element 14G, and the blue light-emitting organic EL element 14B, and prevents the penetration of foreign matters such as water and oxygen. The sealing film 15 may include a first inorganic sealing film, an organic sealing film which is formed on the first inorganic sealing film and functions as a buffer film, and a second inorganic sealing film covering the first inorganic sealing film and the organic sealing film.

Each of the first inorganic sealing film and the second inorganic sealing film may be formed of, for example, a silicon oxide film, a silicon nitride film, or a silicon oxynitride film, or a layered film of these films, formed by CVD using a mask. The organic sealing film is a transparent organic insulating film thicker than the first inorganic sealing film and the second inorganic sealing film, and may be formed of a coatable photosensitive organic material, such as polyimide and acrylic. For example, an ink including such an organic material may be applied by inkjet on a first inorganic sealing film, and then cured by UV irradiation.

The edge cover may be formed of polyimide, acrylic, or the like.

As illustrated in FIG. 7A, laser light is emitted from the glass substrate 1 side, which is a non-flexible substrate, and this causes an ablation to occur at an interface between the underlying PI layer 2 and the glass substrate 1.

Then, as illustrated in FIG. 7B, the glass substrate 1 is peeled from the underlying PI layer 2.

Finally, as illustrated in FIG. 7C, a film substrate 19, which is a flexible substrate, is bonded to the underlying PI layer 2 with an adhesive layer (not illustrated) provided on one face 19a of the film substrate 19 therebetween to complete the flexible organic EL display device 30.

As described above, according to the flexible organic EL display device 30, as illustrated in FIG. 6, since the photosensitive PI layer 10 is formed covering an area having a thin film thickness in the right PI layer inclined area (RPA) of the underlying PI layer 2, the flexible organic EL display device 30 may be realized with a high yield, while suppressing the occurrence of a peeling deficiency in a step (delamination step), included in the LLO step, of peeling the large glass substrate 1 (illustrated in FIG. 7B) from the underlying PI layer 2, even in the underlying PI layer 2 formed with a thin film thickness in the right PI layer inclined area (RPA).

Further, according to the flexible organic EL display device 30, as illustrated in FIG. 6, since the photosensitive PI layer 10 which is a resin layer with which the bending area (BA) is filled is used to cover an area having a thin film thickness in the right PI layer inclined area (RPA) of the underlying PI layer 2, another resin layer only for covering the exposed portion of the underlying PI layer 2 is not required.

Note that, in the present embodiment, a case where the lead wiring line 11d is electrically connected to the gate electrode stretching wiring line 6c is described as an example, but the embodiment is not limited thereto, and the lead wiring line 11d may be electrically connected to, for example, a source electrode stretching wiring line.

In the present embodiment, a case where the underlying PI layer 2 is used as the first polyimide resin layer and the photosensitive PI layer 10 is used as the second polyimide resin layer has been described as an example, but the embodiment is not limited thereto, and a resin layer, other than a polyimide resin layer, which may be peeled from the glass substrate by, for example, being irradiated with laser light may be used.

### Second Embodiment

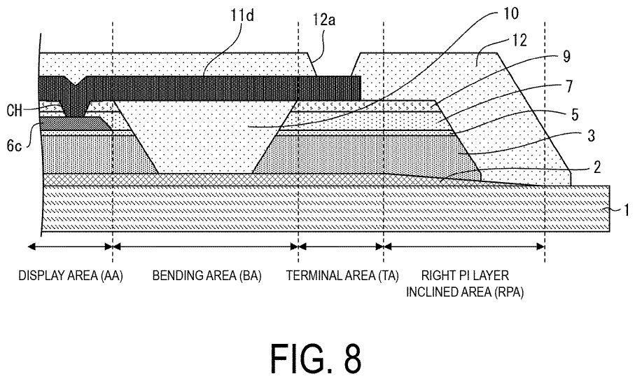

Next, a second embodiment of the disclosure will be described with reference to FIG. 8. The present embodiment is different from the first embodiment in that the photosensitive flattening layer 12 is used instead of the photosensitive PI layer 10 to cover the exposed portion of the underlying PI layer 2, and other aspects of the first embodiment are described as above. For the convenience of description, members having the same functions as those illustrated in the drawings of the first embodiment are denoted by the same reference signs, and the description thereof will be omitted.

FIG. 8 is a diagram for describing a manufacturing process and a schematic configuration of a flexible organic EL display device according to the present embodiment.

As illustrated in FIG. 8, the photosensitive flattening layer 12 as a second polyimide resin layer (second resin layer) is formed such that the exposed portion of the underlying PI layer 2 is covered with the photosensitive flattening layer 12, that is, the exposed portion is a portion where the exposed hole of the underlying PI layer 2 is formed on the underlying PI layer 2 by removing the moisture-proof layer 3, the gate insulating layer 5, the second insulating layer 7, and the third insulating layer 9, and this allows an area having a thin film thickness in the right PI layer inclined area (RPA) of the underlying PI layer 2 to be covered with the photosensitive flattening layer 12.

Note that the photosensitive flattening layer 12 is preferably formed having a film thickness not less than a predetermined film thickness such that the total film thickness of the underlying PI layer 2 and the photosensitive flattening layer 12 in the right PI layer inclined area (RPA) is not less than the film thickness of the underlying PI layer 2 in the display area (AA), the bending area (BA), and the terminal area (TA).

The photosensitive flattening layer 12 is formed covering the third insulating layer 9, the photosensitive PI layer 10 with which the bending area (BA) is filled, and the lead wiring line 11d, in the display area (AA), the bending area (BA), and the terminal area (TA).

According to the flexible organic EL display device illustrated in FIG. 8, since an area having a thin film thickness in the right PI layer inclined area (RPA) of the underlying PI layer 2 is covered with the photosensitive flattening layer 12, a flexible organic EL display device may be realized with a high yield, while suppressing the occurrence of a peeling deficiency in a step (delamination step), included in the LLO step, of peeling the large glass substrate 1 (illustrated in FIG. 7B) from the underlying PI layer 2, even in the underlying PI layer 2 formed with a thin film thickness in the right PI layer inclined area (RPA).

Further, according to the flexible organic EL display device illustrated in FIG. 8, since the photosensitive flattening layer 12 is used to cover the exposed portion of the underlying PI layer 2, another resin layer only for covering the exposed portion of the underlying PI layer 2 is not required.

In the present embodiment, a case where the underlying PI layer 2 is used as a first polyimide resin layer (first resin layer) and the photosensitive flattening layer 12 is used as a second polyimide resin layer (second resin layer) has been described as an example, but the embodiment is not limited thereto, and a resin layer, other than a polyimide resin layer, which may be peeled from the glass substrate by, for example, being irradiated with laser light may be used.

In the present embodiment, among the right PI layer inclined area (RPA), the upper PI layer inclined area (UPA), the lower PI layer inclined area (LPA), and the left PI layer inclined area (not illustrated), which are the frame shaped end region (ER) of the underlying PI layer 2, only the right PI layer inclined area (RPA) of the underlying PI layer 2 is configured to be covered with the photosensitive flattening layer 12 in the exposed portion. However, the embodiment is not limited thereto, and the exposed portion may be covered with the photosensitive flattening layer 12 in one area out of the right PI layer inclined area (RPA), the upper PI layer inclined area (UPA), the lower PI layer inclined area (LPA), and the left PI layer inclined area (not illustrated), or in two areas out of them, or in three areas out of them. In addition, the exposed portions to be covered with the photosensitive flattening layer 12 in all areas (four areas), are more preferable.

### Third Embodiment

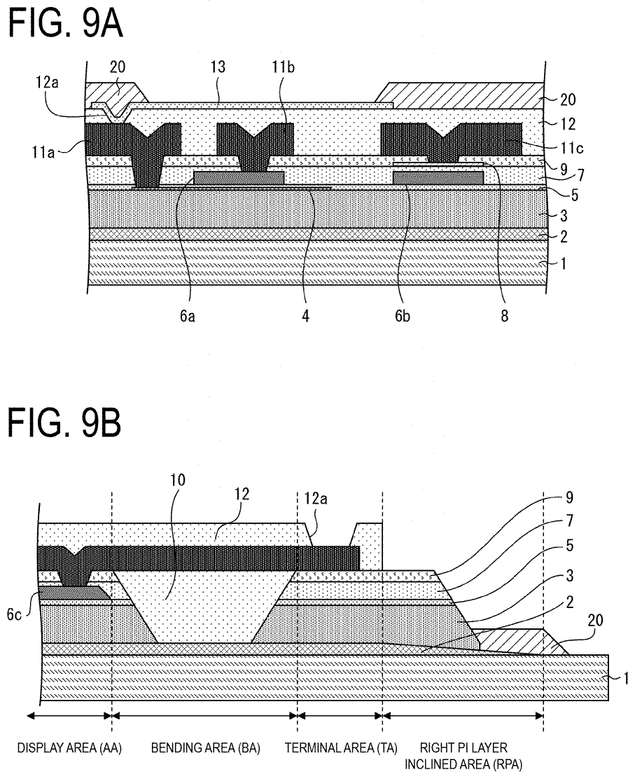

Next, the third embodiment of the disclosure will be described with reference to FIGS. 9A and 9B. The present embodiment is different from the first and second embodiments in that the edge cover layer 20 (the same layer as a layer in which the edge cover is formed) is used instead of the photosensitive PI layer 10 or the photosensitive flattening layer 12 to cover the exposed portion of the underlying PI layer 2, and other aspects of the first and second embodiments are described as above. For the convenience of description, members having the same functions as those illustrated in the drawings of the first and second embodiments are denoted by the same reference signs, and the description thereof will be omitted.

FIGS. 9A and 9B are diagrams for describing a manufacturing process and a schematic configuration of a flexible organic EL display device according to the present embodiment.

FIG. 9A is a diagram illustrating a schematic configuration of the display area (AA) of the flexible organic EL display device, and FIG. 9B is a diagram illustrating a schematic configuration of the display area (AA), the bending area (BA), the terminal area (TA), and the right PI layer inclined area (RPA) of the flexible organic EL display device.

As illustrated in FIG. 9A, in the display area (AA) of the flexible organic EL display device, a semiconductor layer 4 is formed into a predetermined shape on the moisture-proof layer 3, and the gate insulating layer 5 is formed covering the moisture-proof layer 3 and the semiconductor layer 4.

On the gate insulating layer 5, a gate electrode 6a and a capacitance electrode 6b are formed into a predetermined shape, and the second insulating layer 7 is formed covering the gate insulating layer 5, the gate electrode 6a, the capacitance electrode 6b, and the gate electrode stretching wiring line 6c (illustrated in FIG. 9B).

Then, as illustrated in the drawings, a drain wiring line 11a in contact with the semiconductor layer 4 in a contact hole configured to make contact between the drain wiring line 11a and the semiconductor layer 4, and a gate wiring line 11b in contact with the gate electrode 6a in a contact hole configured to make contact between the gate wiring line 11b and the gate electrode 6a and a capacitance wiring line 11c in contact with a capacitance counter electrode 8 in a contact hole configured to make contact between the capacitance wiring line 11c and the capacitance counter electrode 8 are formed.

The photosensitive flattening layer 12 is formed covering the third insulating layer 9, the drain wiring line 11a, the gate wiring line 11b, and the capacitance wiring line 11c.

In the display area (AA), an opening 12a is formed in the photosensitive flattening layer 12 at a position overlapping with the drain wiring line 11a in a plan view, and on the photosensitive flattening layer 12, a first electrode (electrode layer) 13 electrically connected to the active element (TFT element in the present embodiment) and a display element (not illustrated) is formed.

The first electrode 13 is electrically connected to the drain wiring line 11a in an opening 12a, and the edge cover layer 20 is formed on the first electrode 13 and the photosensitive flattening layer 12 covering the end portion of the first electrode 13.

The edge cover layer 20 is a polyimide resin including a photosensitive material and may be a positive-working or a negative-working, but in the present embodiment, the positive-working resin in which an opening is formed in an exposed portion is used.

Although a polyimide resin including a photosensitive material is used as the edge cover layer 20 in the present embodiment, the embodiment is not limited thereto, and the edge cover layer 20 may be a polyimide resin not including a photosensitive material. In such a case, the patterning may be formed by dry etching using the resist film formed on a polyimide resin not including a photosensitive material and having a predetermined pattern as a mask.

As illustrated in FIG. 9B, an exposed portion of the underlying PI layer 2, which is a first polyimide resin layer (first resin layer), is covered with the edge cover layer 20 (the edge cover layer 20 which is the same layer as a layer in which the edge cover is formed), which is a second polyimide resin layer (second resin layer).

That is, the edge cover layer 20 as the second polyimide resin layer is formed such that the exposed portion of the underlying PI layer 2 is covered with the edge cover layer 20, here, the exposed portion is a portion where the exposed hole of the underlying PI layer 2 is formed on the underlying PI layer 2 by removing the moisture-proof layer 3, the gate insulating layer 5, the second insulating layer 7, and the third insulating layer 9, and this allows an area having a thin film thickness in the right PI layer inclined area (RPA) of the underlying PI layer 2 to be covered with the edge cover layer 20.

Note that the edge cover layer 20 is preferably formed having a film thickness not less than a predetermined film thickness such that the total film thickness of the underlying PI layer 2 and the edge cover layer 20 in the right PI layer inclined area (RPA) is not less than a film thickness of the underlying PI layer 2 in the display area (AA), the bending area (BA), and the terminal area (TA).

According to the flexible organic EL display device illustrated in FIGS. 9A and 9B, since an area having a thin film thickness in the right PI layer inclined area (RPA) of the underlying PI layer 2 is covered with the edge cover layer 20, the flexible organic EL display device may be realized with a high yield, while suppressing the occurrence of a peeling deficiency in a step (delamination step), included in the LLO step, of peeling the large glass substrate 1 (illustrated in FIG. 7B) from the underlying PI layer 2, even in the underlying PI layer 2 formed with a thin film thickness in the right PI layer inclined area (RPA).

Further, according to the flexible organic EL display device illustrated in FIGS. 9A and 9B, since the edge cover layer 20 which is the same layer as the layer in which the edge cover is formed is used to cover the exposed portion of the underlying PI layer 2, another resin layer only for covering the exposed portion of the underlying PI layer 2 is not required.

In the present embodiment, a case where the underlying PI layer 2 is used as the first polyimide resin layer and the edge cover layer 20 is used as the second polyimide resin layer has been described as an example, but the embodiment is not limited thereto, and a resin layer other than a polyimide resin layer which may be peeled from the glass substrate by, for example, being irradiated with laser light may be used.

In the present embodiment, among the right PI layer inclined area (RPA), the upper PI layer inclined area (UPA), the lower PI layer inclined area (LPA), and the left PI layer inclined area (not illustrated), which are the frame shaped end region (ER) of the underlying PI layer 2, only the right PI layer inclined area (RPA) of the underlying PI layer 2 is configured to be covered with the edge cover layer 20 (the same layer as a layer in which the edge cover is formed) in the exposed portion. However, the embodiment is not limited thereto, and the exposed portion may be covered with the edge cover layer 20 (the same layer as a layer in which the edge cover is formed) in one area out of the right PI layer inclined area (RPA), the upper PI layer inclined area (UPA), the lower PI layer inclined area (LPA), and the left PI layer inclined area (not illustrated), or in two areas out of them, or in three areas out of them. In addition, the exposed portions to be covered with the edge cover layer 20 (the same layer as a layer in which the edge cover is formed) in all areas (four areas) are more preferable.

### Fourth Embodiment

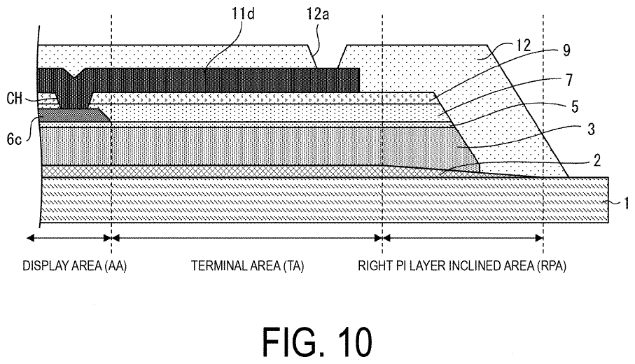

Next, the fourth embodiment of the disclosure will be described with reference to FIG. 10. The present embodiment is different from the second embodiment in that no bending area (BA) is provided, and other aspects of the second embodiment are described as above. For the convenience of description, members having the same functions as those illustrated in the drawings of the second embodiment are denoted by the same reference signs, and the description thereof will be omitted.

FIG. 10 is a diagram for describing a manufacturing process and a schematic configuration of a flexible organic EL display device according to the present embodiment.

As illustrated in FIG. 10, an exposed portion of the underlying PI layer 2 which is a first polyimide resin layer (first resin layer), is covered with the photosensitive flattening layer 12 which is a second polyimide resin layer (second resin layer).

That is, the photosensitive flattening layer 12 as the second polyimide resin layer is formed such that the exposed portion of the underlying PI layer 2 is covered with the photosensitive flattening layer 12, here, the exposed portion is a portion where the exposed hole of the underlying PI layer 2 is formed on the underlying PI layer 2 by removing the moisture-proof layer 3, the gate insulating layer 5, the second insulating layer 7 and the third insulating layer 9, and this allows an area having a thin film thickness in the right PI layer inclined area (RPA) of the underlying PI layer 2 to be covered with the photosensitive flattening layer 12.

Note that the photosensitive flattening layer 12 is preferably formed having a film thickness not less than a predetermined film thickness such that a total film thickness of the underlying PI layer 2 and the photosensitive flattening layer 12 in the right PI layer inclined area (RPA) is not less than a film thickness of the underlying PI layer 2 in the display area (AA) and the terminal area (TA).

According to the flexible organic EL display device illustrated in FIG. 10, since an area having a thin film thickness in the right PI layer inclined area (RPA) of the underlying PI layer 2 is covered with the photosensitive flattening layer 12, a flexible organic EL display device may be realized with a high yield, while suppressing the occurrence of a peeling deficiency in a step (delamination step), included in the LLO step, of peeling the large glass substrate 1 (illustrated in FIG. 7B) from the underlying PI layer 2, even in the underlying PI layer 2 formed with a thin film thickness in the right PI layer inclined area (RPA).

Further, according to the flexible organic EL display device illustrated in FIG. 10, since the photosensitive flattening layer 12 is used to cover the exposed portion of the underlying PI layer 2, another resin layer only for covering the exposed portion of the underlying PI layer 2 is not required.

In the present embodiment, a case where the underlying PI layer 2 is used as the first polyimide resin layer and the photosensitive flattening layer 12 is used as the second polyimide resin layer has been described as an example, but the embodiment is not limited thereto, and a resin layer, other than a polyimide resin layer, which may be peeled from the glass substrate by, for example, being irradiated with laser light may be used.

In the present embodiment, among the right PI layer inclined area (RPA), the upper PI layer inclined area (UPA), the lower PI layer inclined area (LPA), and the left PI layer inclined area (not illustrated), which are the frame shaped end region (ER) of the underlying PI layer 2, only the right PI layer inclined area (RPA) of the underlying PI layer 2 is configured to be covered with the photosensitive flattening layer 12 in the exposed portion. However, the embodiment is not limited thereto, and the exposed portion may be covered with the photosensitive flattening layer 12 in one area out of the right PI layer inclined area (RPA), the upper PI layer inclined area (UPA), the lower PI layer inclined area (LPA), and the left PI layer inclined area (not illustrated), or in two areas out of them, or in three areas out of them. In addition, the exposed portions to be covered with the photosensitive flattening layer 12 in all areas (four areas) are more preferable.

### Fifth Embodiment

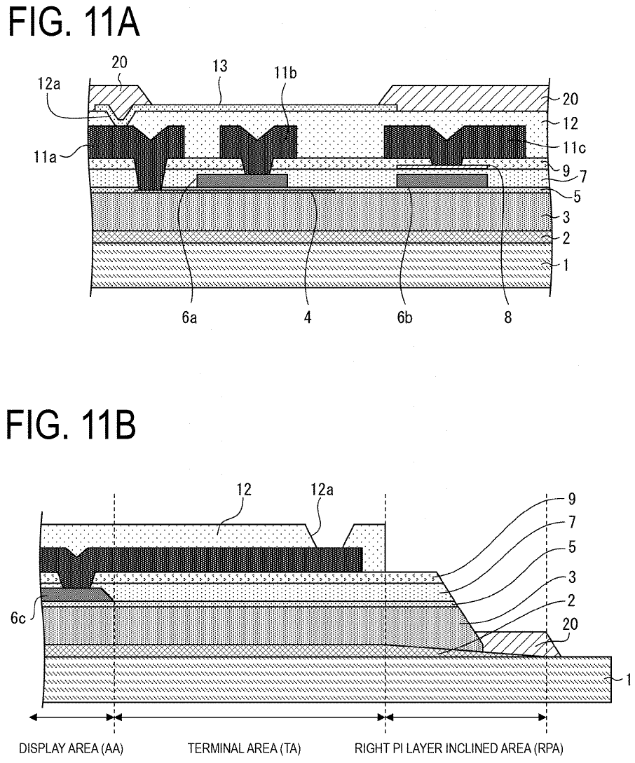

Next, the fifth embodiment of the disclosure will be described with reference to FIGS. 11A and 11B. The present embodiment is different from the third embodiment in that no bending area (BA) is provided, but other aspects of the third embodiment are described as above. For the convenience of description, members having the same functions as those illustrated in the drawings of the third embodiment are denoted by the same reference signs, and the description thereof will be omitted.

FIGS. 11A and 11B are diagrams for describing a manufacturing process and a schematic configuration of a flexible organic EL display device according to the present embodiment.

FIG. 11A is a diagram illustrating a schematic configuration of the display area (AA) of the flexible organic EL display device, and FIG. 11B is a diagram illustrating a schematic configuration of the display area (AA), the terminal area (TA), and the right PI layer inclined area (RPA) of the flexible organic EL display device.

As illustrated in FIG. 11B, an exposed portion of the underlying PI layer 2, which is a first polyimide resin layer (first resin layer), is covered with the edge cover layer 20 (an edge cover layer which is the same layer as a layer in which the edge cover is formed), which is a second polyimide resin layer (second resin layer).

That is, the edge cover layer 20 as the second polyimide resin layer is formed such that the exposed portion of the underlying PI layer 2 is covered with the edge cover layer 20, here, the exposed portion is a portion where the exposed hole of the underlying PI layer 2 is formed on the underlying PI layer 2 by removing the moisture-proof layer 3, the gate insulating layer 5, the second insulating layer 7, and the third insulating layer 9, and this allows an area having a thin film thickness in the right PI layer inclined area (RPA) of the underlying PI layer 2 to be covered with the edge cover layer 20.

Note that the edge cover layer 20 is preferably formed having a film thickness not less than a predetermined film thickness such that a total film thickness of the underlying PI layer 2 and the edge cover layer 20 in the right PI layer inclined area (RPA) is not less than a film thickness of the underlying PI layer 2 in the display area (AA) and the terminal area (TA).

According to the flexible organic EL display device illustrated in FIGS. 11A and 11B, since an area having a thin film thickness in the right PI layer inclined area (RPA) of the underlying PI layer 2 is covered with the edge cover layer 20, a flexible organic EL display device may be realized with a high yield, while suppressing the occurrence of a peeling deficiency in a step (delamination step), included in the LLO step, of peeling the large glass substrate 1 (illustrated in FIG. 7B) from the underlying PI layer 2, even in the underlying PI layer 2 formed with a thin film thickness in the right PI layer inclined area (RPA).

Further, according to the flexible organic EL display device illustrated in FIGS. 11A and 11B, since the edge cover layer 20 which is the same layer as the layer in which the edge cover is formed, is used to cover the exposed portion of the underlying PI layer 2, another resin layer only for covering the exposed portion of the underlying PI layer 2 is not required.

In the present embodiment, a case where the underlying PI layer 2 is used as the first polyimide resin layer and the edge cover layer 20 is used as the second polyimide resin layer has been described as an example, but the embodiment is not limited thereto, and a resin layer other than a polyimide resin layer which may be peeled from the glass substrate by, for example, being irradiated with laser light may be used.

In the present embodiment, among the right PI layer inclined area (RPA), the upper PI layer inclined area (UPA), the lower PI layer inclined area (LPA), and the left PI layer inclined area (not illustrated), which are the frame shaped end region (ER) of the underlying PI layer 2, only the right PI layer inclined area (RPA) of the underlying PI layer 2 is configured to be covered with the edge cover layer 20 (the same layer as a layer in which the edge cover is formed) in the exposed portion. However, the embodiment is not limited thereto, and the exposed portion may be covered with the edge cover layer 20 (the same layer as a layer in which the edge cover is formed) in one area out of the right PI layer inclined area (RPA), the upper PI layer inclined area (UPA), the lower PI layer inclined area (LPA), and the left PI layer inclined area (not illustrated), or in two areas out of them, or in three areas out of them. In addition, the exposed portions to be covered with the edge cover layer 20 (the same layer as a layer in which the edge cover is formed) in all areas (four areas) are more preferable.

### Supplement

To solve the above problem, a method of manufacturing a flexible display device according to aspect 1 of the disclosure is a method of manufacturing a flexible display device including a step of forming a first resin layer on one face of a non-flexible substrate, and the method includes: a first step of forming the first resin layer such that a film thickness in end regions of the first resin layer including four regions of an upper, a lower, a right, and a left region surrounding a central region of the first resin layer is thinner than a film thickness in the central region of the first resin layer; a second step of forming one or more inorganic films on the first resin layer; a third step of exposing the first resin layer by removing at least a portion of the one or more inorganic films in at least one of the four regions in the end regions of the first resin layer; a fourth step of forming a second resin layer on the first resin layer in a region in which the first resin layer is exposed, among the four regions in the end regions of the first resin layer; a fifth step of emitting laser light from a side of the non-flexible substrate to peel the non-flexible substrate; and a sixth step of bonding a flexible substrate to a surface from which the non-flexible substrate is peeled.

According to the above method, since the second resin layer is formed on the first resin layer in at least one of the four regions in the end regions of the first resin layer, a flexible display device may be realized, while suppressing the occurrence of a peeling deficiency in a step (delamination step), included in the LLO step, of peeling a large glass substrate from the first resin layer, even in the first resin layer formed with a thin film thickness.

In the method of manufacturing a flexible display device according to aspect 2 of the disclosure, in aspect 1, a bending area includes a portion of the central region of the first resin layer, in the third step, the bending area is formed, the bending area being a region from which at least a portion of the one or more inorganic films formed in the second step is removed, and in the fourth step, the bending area may be filled with the second resin layer.

According to the above method, the second resin layer is formed on the first resin layer in the end region of the first resin layer, and the bending area is filled with the second resin layer.

In the method of manufacturing a flexible display device according to aspect 3 of the disclosure, in aspect 1, in the fourth step, the second resin layer may be formed covering the one or more inorganic films in the central region of the first resin layer.

According to the above method, the second resin layer is formed on the first resin layer in the end region of the first resin layer and is formed covering the one or more inorganic films in the central region of the first resin layer.

In the method of manufacturing a flexible display device according to aspect 4 of the disclosure, in aspect 1, a display area including a display element includes a portion of the central region of the first resin layer, the display element includes an electrode layer as a lowermost layer, and the second resin layer may be formed of the same layer as a layer in which an edge cover is formed surrounding the periphery of the electrode layer.

According to the above method, the second resin layer may be formed of the same layer as a layer in which an edge cover is formed surrounding the periphery of the electrode layer.

In the method of manufacturing a flexible display device according to aspect 5 of the disclosure, in any one of aspects 1 to 4, in the fourth step, in the region where the first resin layer is exposed among the four regions in the end region of the first resin layer, the second resin layer may be formed such that a total film thickness of the first resin layer and the second resin layer is not less than a film thickness of the first resin layer in the central region of the first resin layer.

According to the above method, in the step of peeling the large glass substrate from the first resin layer (delamination step), a flexible display device may be realized while suppressing the occurrence of a peeling deficiency.

In the method of manufacturing a flexible display device according to aspect 6 of the disclosure, in any one of aspects 1 to 5, in the third step, the first resin layer may be exposed by removing at least a portion of the one or more inorganic films in all of the four regions in the end regions of the first resin layer.

According to the above method, in the step of peeling the large glass substrate from the first resin layer (delamination step), a flexible display device may be realized while further suppressing the occurrence of a peeling deficiency.

In the method of manufacturing a flexible display device according to aspect 7 of the disclosure, in any one of aspects 1 to 6, the first resin layer and the second resin layer are preferably polyimide resin.

According to the above method, a flexible display device including layers formed from a polyimide resin, the layers being configured to prevent moisture and impurities more efficiently from penetrating, may be realized.

In the method of manufacturing a flexible display device according to aspect 8 of the disclosure, in any one of aspects 1 to 7, the second resin layer preferably includes a photosensitive material.

According to the above method, the second resin layer may be patterned by exposure and development.

In the method of manufacturing a flexible display device according to aspect 9 of the disclosure, in any one of aspects 1 to 8, in the first step, the first resin layer may be formed by using a slit coater.

According to the above method, the first resin layer may be formed by using a slit coater.

To solve the above problem, a non-flexible substrate including a display element according to aspect 10 of the disclosure is a non-flexible substrate including a display element on one face of the non-flexible substrate, wherein a first resin layer is formed on the one face and below the display element, a film thickness in end regions of the first resin layer including four regions of an upper, a lower, a right, and a left region surrounding a central region of the first resin layer is thinner than a film thickness in the central region of the first resin layer, and one or more inorganic films is formed on the first resin layer, a second resin layer covering the first resin layer exposed from the one or more inorganic films is formed in at least one of the four regions in the end regions of the first resin layer.

According to the above configuration, since the second resin layer covering the first resin layer exposed from the one or more inorganic films is formed in at least one of the four regions in the end regions of the first resin layer, a non-flexible substrate including a display element may be realized with a high yield, while suppressing the occurrence of a peeling deficiency in a step (delamination step), included in the LLO step, of peeling a large glass substrate from the first resin layer even in the first resin layer formed with a thin film thickness.

The non-flexible substrate including a display element according to aspect 11 of the disclosure may be configured such that, in aspect 10, a bending area includes a portion of the central region of the first resin layer, the bending area is an area from which at least a portion of the one or more inorganic films is removed, and the bending area is filled with the second resin layer.

According to the above configuration, the second resin layer is formed on the first resin layer in the end regions of the first resin layer, and the bending area is filled with the second resin layer.

In the non-flexible substrate including a display element according to aspect 12 of the disclosure, in aspect 10, the second resin layer may be formed covering the one or more inorganic films in the central region of the first resin layer.

According to the above configuration, the second resin layer is formed on the first resin layer in the end regions of the first resin layer and is formed covering the one or more inorganic films in the central region of the first resin layer.

The non-flexible substrate including a display element according to aspect 13 of the disclosure may be configured, in aspect 10, such that the display area including the display element includes a portion of the central region of the first resin layer, the display element includes an electrode layer as a lowermost layer, and the second resin layer surrounds the periphery of the electrode layer in the display area.

According to the above configuration, the second resin layer surrounds the periphery of the electrode layer in the display area.

In the non-flexible substrate including a display element according to aspect 14 of the disclosure, in any one of aspects 10 to 13, in the region where the first resin layer is exposed among the four regions in the end regions of the first resin layer, the second resin layer may be formed with a total film thickness of the first resin layer and the second resin layer being not less than a film thickness of the first resin layer in the central region of the first resin layer.

According to the above configuration, in the step of peeling the large glass substrate from the first resin layer (delamination step), a non-flexible substrate including a display element may be realized with a high yield which suppressing the occurrence of a peeling deficiency.

In the non-flexible substrate including a display element according to aspect 15 of the disclosure, in any one of aspects 10 to 14, the second resin layer covering the first resin layer exposed from the one or more inorganic films may be formed in all of the four regions in the end regions of the first resin layer.

According to the above configuration, in the step of peeling the large glass substrate from the first resin layer (delamination step), a non-flexible substrate including a display element may be realized with a high yield which further suppressing the occurrence of a peeling deficiency.

In the non-flexible substrate including a display element according to aspect 16 of the disclosure, in any one of aspects 10 to 15, the first resin layer and the second resin layer may be polyimide resin.

According to the above configuration, a polyimide resin layer is provided, which is a layer configured to prevent moisture and impurities more efficiently from penetrating.

In the non-flexible substrate including a display element according to aspect 17 of the disclosure, in any one of aspects 10 to 16, the second resin layer preferably includes a photosensitive material.

According to the above configuration, the second resin layer may be patterned by exposure and development.

In the non-flexible substrate including a display element according to aspect 18 of the disclosure, in any one of aspects 10 to 17, the display element may be an organic EL display element.

According to the above configuration, a non-flexible substrate including an organic EL display element may be realized.

In the non-flexible substrate including a display element according to aspect 19 of the disclosure, in any one of aspects 10 to 17, the display element may be a reflection type liquid crystal display element.

According to the above configuration, a non-flexible substrate including a reflection type liquid crystal display element may be realized.

### Additional Items

The disclosure is not limited to each of the embodiments stated above, and various modifications may be implemented within a range not departing from the scope of the claims. Embodiments obtained by appropriately combining technical approaches stated in each of the different embodiments also fall within the scope of the technology of the disclosure. Moreover, novel technical features may be formed by combining the technical approaches stated in each of the embodiments.

### INDUSTRIAL APPLICABILITY

The disclosure may be utilized in a non-flexible substrate including a display element, and a method of manufacturing a flexible display device.

### REFERENCE SIGNS LIST

1 Glass substrate (Non-flexible substrate)
1u Organic EL display device
2 Underlying PI layer (first resin layer)
3 Moisture-proof layer (inorganic film)
4 Semiconductor layer
5 Gate insulating layer (inorganic film)
6a Gate electrode
6b Capacitance electrode
6c Gate electrode stretching wiring line
7 Second insulating layer (inorganic film)
8 Capacitance counter electrode
9 Third insulating layer (inorganic film)
10 Photosensitive PI layer (second resin layer)
11a Drain wiring line
11b Gate wiring line
11c Capacitance wiring line
11d Lead wiring line
12 Photosensitive flattening layer (second resin layer)
12a Opening
13 First electrode (electrode layer)
14 Display element
15 Sealing film
19 Film substrate (flexible substrate)
20 Edge cover layer (second resin layer)
30 Flexible organic EL display device (flexible display device)
AA Display area
BA Bending area
TA Terminal area
CR Central region of underlying PI layer
RPA Right PI layer inclined area
UPA Upper PI layer inclined area
LPA Lower PI layer inclined area
ER End region of underlying PI layer
CH Contact hole
BH Bending hole
PH Exposed hole of underlying PI layer

1: A method of manufacturing a flexible display device including forming a first resin layer on one face of a non-flexible substrate, the method comprising:
a first step of forming the first resin layer such that a film thickness in end regions of the first resin layer including four regions of an upper, a lower, a right, and a left region surrounding a central region of the first resin layer is thinner than a film thickness in the central region of the first resin layer;
a second step of forming one or more inorganic films on the first resin layer;
a third step of exposing the first resin layer by removing at least a portion of the one or more inorganic films in at least one of the four regions in the end regions of the first resin layer;
a fourth step of forming a second resin layer on the first resin layer in a region in which the first resin layer is exposed, among the four regions in the end regions of the first resin layer;
a fifth step of emitting laser light from a side of the non-flexible substrate to peel the non-flexible substrate; and
a sixth step of bonding a flexible substrate to a surface from which the non-flexible substrate is peeled.

2: The method of manufacturing a flexible display device according to claim 1,
wherein a bending area includes a portion of the central region of the first resin layer,
in the third step, the bending area is formed, the bending area being a region from which at least a portion of the one or more inorganic films formed in the second step is removed, and
in the fourth step, the bending area is filled with the second resin layer.

3: The method of manufacturing a flexible display device according to claim 1,
wherein in the fourth step, the second resin layer is formed covering the one or more inorganic films in the central region of the first resin layer.

4: The method of manufacturing a flexible display device according to claim 1,
wherein a display area including a display element includes a portion of the central region of the first resin layer,
the display element includes an electrode layer as a lowermost layer, and
the second resin layer is formed of the same layer as a layer in which an edge cover is formed surrounding a periphery of the electrode layer.

5: The method of manufacturing a flexible display device according to claim 1,
wherein, in the fourth step, in the region where the first resin layer is exposed among the four regions in the end regions of the first resin layer, the second resin layer is formed such that a total film thickness of the first resin layer and the second resin layer is not less than a film thickness of the first resin layer in the central region of the first resin layer.

6: The method of manufacturing a flexible display device according to claim 1,
wherein, in the third step, the first resin layer is exposed by removing at least a portion of the one or more inorganic films in all of the four regions in the end regions of the first resin layer.

7: The method of manufacturing a flexible display device according to claim 1,
wherein the first resin layer and the second resin layer are polyimide resin.

8: The method of manufacturing a flexible display device according to claim 1,
wherein the second resin layer includes a photosensitive material.

9: The method of manufacturing a flexible display device according to claim 1,
wherein, in the first step, the first resin layer is formed by using a slit coater.

10: A non-flexible substrate comprising:
a display element on one face of the non-flexible substrate,
wherein a first resin layer is formed on the one face and below the display element,
a film thickness in end regions of the first resin layer including four regions of an upper, a lower, a right, and a left region surrounding a central region of the first resin layer is thinner than a film thickness in the central region of the first resin layer,
one or more inorganic films is formed on the first resin layer, and
a second resin layer covering the first resin layer exposed from the one or more inorganic films is formed in at least one of the four regions in the end regions of the first resin layer.

11: The non-flexible substrate including a display element according to claim 10,
wherein a bending area includes a portion of the central region of the first resin layer,
the bending area is an area from which at least a portion of the one or more inorganic films is removed, and
the bending area is filled with the second resin layer.

12: The non-flexible substrate including a display element according to claim 10,
wherein the second resin layer is formed covering the one or more inorganic films in the central region of the first resin layer.

13: The non-flexible substrate including a display element according to claim 10,
wherein a display area including the display element includes a portion of the central region of the first resin layer,
the display element includes an electrode layer as a lowermost layer, and
the second resin layer surrounds a periphery of the electrode layer in the display area.

14: The non-flexible substrate including a display element according to claim 10,
wherein, in the region where the first resin layer is exposed among the four regions in the end regions of the first resin layer, the second resin layer is formed with a total film thickness of the first resin layer and the second resin layer being not less than a film thickness of the first resin layer in the central region of the first resin layer.

15: The non-flexible substrate including a display element according to claim 10,
wherein the second resin layer covering the first resin layer exposed from the one or more inorganic films is formed in all of the four regions in the end regions of the first resin layer.

16: The non-flexible substrate including a display element according to claim 10,
wherein the first resin layer and the second resin layer are polyimide resin.

17: The non-flexible substrate including a display element according to claim 10,
wherein the second resin layer includes a photosensitive material.

18: The non-flexible substrate including a display element according to claim 10,
wherein the display element is an organic EL display element.

19: The non-flexible substrate including a display element according to claim 10,
wherein the display element is a reflection type liquid crystal display element.
